(19) United States
(12) Patent Application Publication
(10) Pub. No.: US 2011/0228821 A1
(43) Pub. Date: Sep. 22, 2011

(54) ADAPTIVE EQUALIZING REPEATER WITH OUTPUT CONTROL

(75) Inventors: Allard VAN DER HORST, Monmouthshire (GB); Andrew SHARRATT, Bristol (GB); Ben WILLCOCKS, Bristol (GB); Chris BORN, Bristol (GB); Miguel MARQUINA, Bristol (GB)

(73) Assignee: PHYWORKS LIMITED, Bristol (GB)

(21) Appl. No.: 12/725,746

(22) Filed: Mar. 17, 2010

(51) Int. Cl. H04B 3/36; H04L 25/20; H03H 7/40; H04B 1/10

(52) U.S. Cl. 375/211; 375/232; 375/346

(57) ABSTRACT

A repeater includes at least an adaptive equalizer able to equalize a received signa. An adaptation function that determines the optimal equalizer settings based on the received signal is either integrated in the repeater or closely associated with the repeater. The repeater also has the capability to mute the output signal under control of the adaptation logic, while receiving an input signal which is used to perform the adaptation function.

### TECHNICAL FIELD OF THE INVENTION

The present invention relates to an adaptive equalizer, especially to a repeater which includes an adaptive equalizer to compensate for the distortion introduced by a communications channel and in particular to repeater which supports multiple data rates.

### BACKGROUND OF THE INVENTION

In many communications systems, a connection between two entities can be established at a one of a multitude of data rates. To establish at what rate is supported by both entities, a process called rate negotiation is performed. One implementation of such a rate negotiation process (as implemented in Fibre Channel systems) employs a sequence where the transmitter cycles through its supported rates and the receiver attempts to receive data at all of its supported rates. The transmitter and receiver processes are independent from each other and it is a fundamental requirement that the receiver cycles faster than the transmitter. The transmitter will start this process as soon as possible to enable detection by the receiver. The receiver will attempt data recovery as soon as any signal is received.

This negotiation process has timers associated with it, to ensure that the information exchange takes a reasonable time. If such a timer expires before both entities have agreed that they both support a specific rate, it is assumed that this particular rate cannot be supported by the system.

In systems where the link between both systems causes little degradation of the signal at all supported rates, the above process will result in both systems establishing a communication link at the highest speed supported by both.

In many modern systems however, the receiver must deal with the fact that the received signal will not be a perfect copy of the transmitted bit sequence, but will show the effects of changes to the waveform introduced by the communications medium, and will include an additional noise component.

For many communications media, a key source of changes to the waveform is inter-symbol interference (ISI). That is, energy from one bit period is received in another bit period.

The presence of ISI greatly increases the probability that the receiver will fail to determine correctly whether a specific transmitted bit was a “1” or a “0”. That is, it greatly increases the probability of bit errors. It is common understanding that, for a given channel, the error-rate caused by ISI increases if the bit rate of the signal over the channel increases. If the errors for a given data rate exceed a specified limit, the channel is deemed not to support this specific data rate.

It is known, however, that it is possible to compensate for ISI. A particular transmitted waveform results in a particular received waveform, and the relationship between the transmitted waveform and the received waveform can be expressed mathematically as a transfer function (“channel transfer function”). An equalizer can be provided in the receiver, which applies a second transfer function to the received waveform. If the second transfer function can be made to approximate the inverse of the first transfer function, then the effects of ISI can be approximately compensated. This approach is known as equalization. Examples of equalization are feed forward equalization and decision feedback equalization. For example U.S. Pat. No. 7,170,930 describes such an adaptive equalizer.

With the increase in communication data rates, many systems contain channels which experience high levels of ISI. Such channels would benefit from equalization to compensate for the changes to the waveform introduced by the communications medium. Such equalization can be fixed or adaptive.

Fixed equalization is common in these types of systems, as this does not require any training to determine the right level of equalization. However, this makes the system inflexible, as the equalization has to be tuned at system manufacturing time.

Adaptive equalization is attractive as it will automatically compensate for the different changes that can be introduced by different links. This enables interoperability of different subsystems in the system. The drawback of adaptive equalization is that compensation for the first transfer function requires the equalizer to be adapted using knowledge of the first transfer function. When the equalizer can independently determine this information, this is referred to as an adaptive equalizing receiver.

In many cases the adaptive equalization function is added to the system as a separate block, in which case the equalizer will be implemented as a repeater. FIG. 2 shows such a repeater. It will be appreciated by one skilled in the art that a repeater is a unit for receiving an input data signal and outputting an output data signal which corresponds to substantially the same data. In the case of a repeater having an equalizer the equalizer applies a transfer function to the received input data signal to determine the appropriate output data signal.

FIG. 1 is a block schematic diagram illustrating an example system in which said equalizer is required. The system transmitter [001] provides a signal to be transmitted over a channel [002]. This signal is received by a repeater [003], which corrects for the channel impairment. The repeater output signal is provided to the system receiver [004].

FIG. 2 is a block schematic diagram illustrating an equalizing repeater for binary-valued symbols, having adaptation functionality integrated. The signal is received at input [101], and is provided to the equalizer block [103]. The output of the equalizer is provided to the output stage [104]. The settings of the equalizer are controlled by the integrated adaptation functionality [105].

FIG. 3 is a block schematic diagram illustrating an equalizing repeater for binary-valued symbols, having external adaptation functionality. The signal is received at input [201], and is provided to the equalizer block [203]. The output of the equalizer is provided to the output stage [204]. The settings of the equalizer are controlled by the external adaptation functionality [205].

### SUMMARY OF THE INVENTION

According to the present invention there is provided an equalizing repeater for receiving an input signal and outputting an output data signal, said output data signal being based on the input data signal and at least one equalizer setting, wherein the repeater is configured to mute said output data signal whilst said equalizer settings are being adapted to an input data signal provided for establishing a connection.

The repeater thus comprises an equalizer with adaptation functionality and an output that can be muted. The repeater may also comprise a quantizer which may form part of equalizer. The equalizer has associated circuitry, the circuitry being adapted to calculate the optimum equalization and quantization parameters based on statistical measurements taken in connection with signals having the corresponding value of one or more previously received signal. This circuitry can be integrated in the repeater or provided externally to the receiver.

When the repeater output is placed in the muted state, this output will not present any signal transitions and means that the repeater is arranged so that substantially no output data signal is transmitted, for instance to a receiver. This can be achieved for example by placing the output in high-impedance mode or place a constant “0” or “1” signal on the output, i.e. a “no-data” signal.

Whilst the equalizer settings are being adjusted, e.g. during adaptation convergence, the equalizer transfer function does not represent the exact inverse of the channel transfer function. Therefore any output from the repeater at this stage would not yet represent the original transmitted signal. This means that a receiving end-point (which receives the output of the repeater) would receive data that has not been correctly equalized. At this point it is likely that the receiving end-point would decide that the rate currently transmitted by the transmitting end-point is not supported by the channel.

According to embodiments of the present invention the output of the repeater is kept in a muted state while the adaptation is performed, and is unmuted after the adaptation has achieved a stable state. A time limit can be applied to the muting to ensure that the system does not permanently remain in this initial state, i.e. the output data signal may be muted until a successful level of adaptation converge is achieved, or until a certain time period, e.g. a first time period, has elapsed or whichever of convergence and elapse of the time period occurs first.

An advantage of such a repeater is that the addition of a mute controlled by the equalization status enables the adaptive equalizer to be placed in front of the receiving end-point while preserving the nature of this end-point. A fully compliant system can be implemented, supporting multi-rate operation without any additional handshaking signals being required between the adaptive equalizer and the end-point receiver. The receiving end point need not know whether or not a repeater is present. However the receiving end point only receives data signals to which a satisfactory level of equalization can be applied. Only when the receiving end point receives such data signals will it attempt to determine whether such a data rate can be supported.

An external equalizer can thus be fitted without mandating any additional signaling to the receiving end-point. No additional training sequence is required, as the actual handshaking data can be used to determine the optimum equalizer settings. Thus the present invention also relates to a receiver system comprising an equalizing repeater as described above and a multi-rate receiver unit wherein the equalizing repeater is configured to receive an input to the receiver system as said input data signal and the receiver unit is configured to receive said output data signal from said equalizing repeater.

The adaptive equalizer can perform its adaptation, while the output from the repeater is muted, thereby indicating that the optimum adaptation has not yet been achieved. The muting function effectively indicates to the receiving end-point that there is not yet a valid transmitting end-point.

In another aspect there is provided a method of applying equalization to an input data signal comprising the steps of: receiving an input data signal provided for establishing a connection; performing an adaptation process to adjust settings of an equalizer based on said input data signal; and subsequently outputting an output data signal based on said input data signal and said equalizer settings; wherein during said adaptation process said output signal is muted. As described above the input signal provided for establishing connection may be provided at a plurality of data rates for rate negotiation.

The output data signal may be muted until the adaptation process is completed, or for a first period of time, or until either the adaptation process is completed or a first period of time elapses. The output data signal may be muted by outputting a fixed no-data signal such as a “1” or a “0”.

The invention also applies to a method of establishing a connection between a transmitter and a receiver comprising the steps of: receiving an input data signal from a transmitted provided to establish a connection; performing the equalization method described above to equalize the input data signal; receiving said output data signal at a receiver; and using said output data signal at said receiver to establish a connection with said transmitter. The input data signal may comprise a data rate negotiation signal.

In a further aspect a multi-rate equalizing module comprises an adaptive equalizer configured to perform equalization on an input data signal wherein the equalizing module is configured to provide an equalized output signal only after an initial adaptation process is completed. The equalizing module may be implemented within a receiver unit or as an external component and may be retro-fitted to a receiving unit to extend the flexibility of the receiving end-unit but without requiring any further modification to the receiving end unit. Importantly the equalizing module need not be controlled by the same control as for receiver.

### BRIEF DESCRIPTION OF THE DRAWINGS

For a better understanding of the present invention, and to show more clearly how it may be carried into effect, reference will now be made, by way of example, to the following drawings, in which:

FIG. 1 is a block schematic diagram illustrating an example system in which said equalizer is required.

FIG. 2 is a block schematic diagram illustrating an equalizing repeater for binary-valued symbols, having adaptation functionality integrated.

FIG. 3 is a block schematic diagram illustrating an equalizing repeater for binary-valued symbols, having external adaptation functionality.

FIG. 4 illustrates an equalizing repeater according to the present invention.

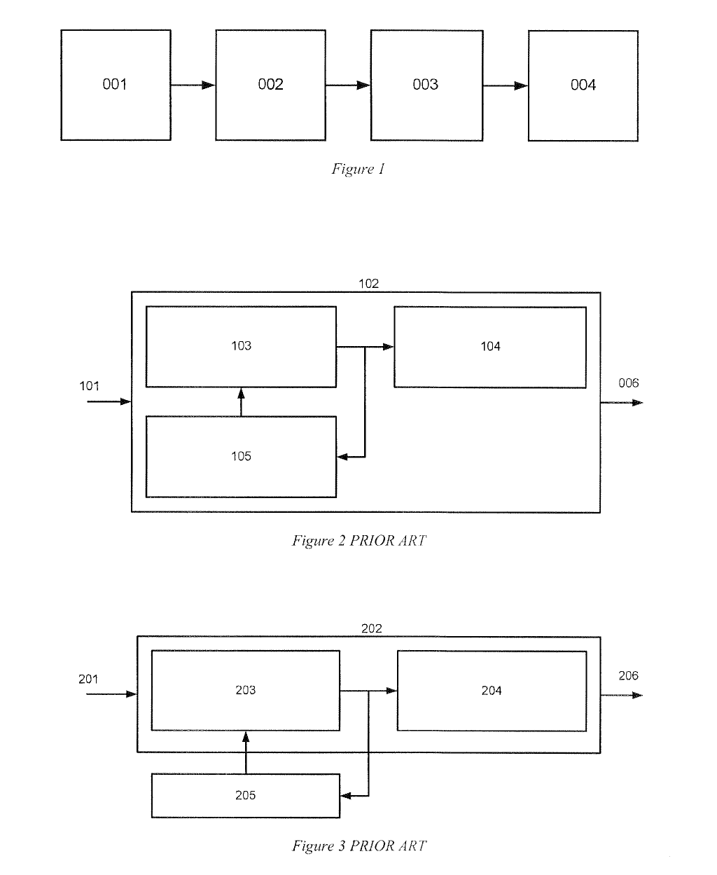

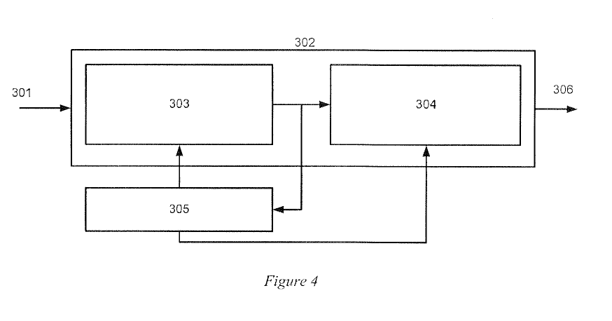

### DETAILED DESCRIPTION OF THE INVENTION

In this embodiment, rather than always presenting the equalized received signal to the output of the repeater, the output is kept muted while the adaptation of the equalizer completes. The state of the adaptation is compared against set targets or maximum time and only when said targets are met, or time has elapsed, the output is un-muted.

Thus, the repeater [302] receives an input signal on an input line [301]. The input signal may have for example been received along a PCB trace. The signal is applied to the input of the equalization block [303].

The adaptation block [305] receives internal information which is used to determine the optimum equalizer settings. These settings control the equalizer [303].

While the adaptation block is collecting information and converges the equalizer settings to the optimum value, the output stage [304] is muted.

When the adaptation block has converged, or after a set time limit has expired, the output stage will be unmuted, providing equalizer data to the next receiver [306] in the system.

This invention is particularly applicable to end-points that have been designed to communicate over channels that have little or no signal degradation. When such end-points have to be used in systems with channels that distort the signal due to ISI or other signal impairments, the addition of an external equalizing repeater is the most effective way to enable the end-points to communicate at the highest possible data rate.

To make interoperability between independently supplied end-points possible over channels which characteristics are not known at system design time, adaptive equalization is required. An adaptive equalizer with mute control enables the equalizer to receive enough data to adapt on, while maintaining existing operation in the end-points. In particular:

No new training sequence is required from the transmitting end-point; and

No new handshaking is required with the receiving end-point

While the foregoing written description of the invention enables one of ordinary skill to make and use what is considered presently to be the best mode thereof, those of ordinary skill will understand and appreciate the existence of variations, combinations, and equivalents of the specific embodiment, method, and examples herein. The invention should therefore not be limited by the above described embodiment, method, and examples, but by all embodiments and methods within the scope and spirit of the invention.

We claim:

1. An equalizing repeater comprising an adaptive equalizer for receiving an input data signal and outputting an output data signal, said output data signal being based on the input data signal and at least one equalizer setting, wherein the repeater is configured to mute said output data signal whilst said equalizer settings are being adapted to an input data signal provided for establishing a connection.

2. An equalizing repeater as claimed in claim 1 wherein said adaptive equalizer is a multi-rate equalizer for receiving a signal at a plurality of possible data rates and wherein said input data signal provided for establishing a connection is an input data signal for data rate negotiation with a receiver.

3. An equalizing repeater as claimed in claim 1 wherein, in response to said input data signal provided for establishing a connection, said adaptive equalizer performs an adaptation convergence process and wherein the output data signal is muted until said adaptation convergence process is completed.

4. An equalizing repeater as claimed in claim 1 wherein , in response to said input data signal provided for establishing a connection said output data signal is muted for a first period of time.

5. An equalizing repeater as claimed in claim 1 wherein, in response to said input data signal provided for establishing a connection said adaptive equalizer performs an adaptation convergence process and wherein the output data signal is muted until either said adaptation convergence process is completed or a first period of time elapses.

6. An equalizing repeater as claimed in claim 1, wherein, the repeater is configured to mute the output signal by outputting a fixed output signal.

7. A receiver system comprising an equalizing repeater as claimed in claim 2 and a multi-rate receiver unit wherein said equalizing repeater is configured to receive an input to the receiver system as said input data signal and said receiver unit is configured to receive said output data signal from said equalizing repeater.

8. A method of applying equalization to an input data signal comprising the steps of:
receiving an input data signal provided for establishing a connection;
performing an adaptation process to adjust settings of an equalizer based on said input data signal; and subsequently
outputting an output data signal based on said input data signal and said equalizer settings; wherein
during said adaptation process said output data signal is muted.

9. A method as claimed in claim 8 wherein said input data signal provided for establishing connection is a provided at a plurality of data rates for rate negotiation.

10. A method as claimed in claim 8 wherein said output data signal is muted until the adaptation process is completed.

11. A method as claimed in claim 8 wherein said output data signal is muted for a first period of time.

12. A method as claimed in claim 8 wherein said output data signal is muted until either the adaptation process is completed or until a first period of time elapses.

13. A method as claimed in claim 8 wherein said output data signal is muted by outputting a fixed output signal.

14. A method of establishing a connection between a transmitter and a receiver comprising the steps of:
receiving an input data signal from a transmitted provided to establish a connection;
performing the method of claim 8 to equalize said input data signal;
receiving said output data signal at a receiver;
and using said output data signal at said receiver to establish a connection with said transmitter.

15. A method as claimed in claim 14 wherein said input data signal comprises a data rate negotiation signal.

16. A multi-rate equalizing module comprising an adaptive equalizer configured to perform equalization on an input data signal wherein the equalizing module is configured to provide an equalized output signal only after an initial adaptation process is completed.

17. An equalizing module as claimed in claim 16 wherein the initial adaption process is completed based on at least one of a predetermined adaption converge and a predetermine length of time.

18. An equalizing module as claimed in claim 16 wherein the initial adaptation process is performed in receipt of an input signal provided for data rate negotiation.
